(19) United States
(12) Patent Application Publication
(10) Pub. No.: US 2004/0188722 A1
(43) Pub. Date: Sep. 30, 2004

(54) Solid state image device and method of fabricating the same

(75) Inventors: Makoto Izumi, Motosu-gun (JP); Mitsuru Okigawa, Nagoya-shi (JP); Kazuhiro Sasada, Hashima-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/799,610

(22) Filed: Mar. 15, 2004

(30) Foreign Application Priority Data
Mar. 24, 2003 (JP) JP2003-80662

(51) Int. Cl. H01L 29/06

(52) U.S. Cl. 257/215

(57) ABSTRACT

A solid state image device capable of improving charge transfer efficiency by reducing the interval between adjacent gate electrodes and reducing power consumption by reducing parasitic capacitances while obtaining a signal having small noise is provided. This solid state image device comprises a first gate electrode, formed on a gate insulator film, having a substantially flat upper surface and a second gate electrode formed on the gate insulator film through an insulator film having a thickness smaller than the minimum limit dimension of lithography to be adjacent to the first gate electrode without overlapping the first gate electrode.

### BACKGROUND OF THE INVENTION

1. Field of the Invention

The present invention relates to a solid state image device such as a charge-coupled device (CCD) and a method of fabricating the same, and more particularly, it relates to a solid state image device having a plurality of gate electrodes arranged at a prescribed interval and a method of fabricating the same.

2. Description of the Background Art

A charge-coupled device (CCD) employed for an image sensor or the like is known in general. In relation to the charge-coupled device, a charge-coupled device having a single-layer gate electrode structure and that having a two-layer gate electrode structure are known. For example, Japanese Patent Laying-Open No. 11-204776 (1999) discloses a charge-coupled device having a two-layer gate electrode structure. In the charge-coupled device having a two-layer gate electrode structure, the gate electrode structure is generally formed by patterning a film for forming gate electrodes by lithography. Therefore, it is disadvantageously difficult to reduce the interval between the gate electrodes beyond the minimum limit dimension of lithography.

On the other hand, charge transfer efficiency can be improved in the charge-coupled device by reducing the interval between adjacent gate electrodes. Further, the areas of the gate electrodes can be increased by reducing the interval between the adjacent gate electrodes, thereby increasing the area of a region for storing electrons. Thus, the quantity of saturation charges is so increased that a signal having small noise can be obtained. In a conventional charge-coupled device having a general single-layer gate electrode structure, however, it is difficult to reduce the interval between gate electrodes beyond the minimum limit dimension of lithography as hereinabove described, and hence it is difficult to further improve charge transfer efficiency while obtaining a signal having small noise.

In a conventional charge-coupled device having a two-layer electrode structure, first and second gate electrodes overlap each other through an insulator film. When the thickness of the insulator film located between first and second electrode layers is reduced beyond the minimum limit dimension of lithography, therefore, the interval between the gate electrodes can be reduced beyond the minimum limit dimension of lithography.

FIG. 11 is a sectional view showing the structure of a conventional charge-coupled device having a two-layer gate electrode structure. Referring to FIG. 11, a gate insulator film 102 is formed on a semiconductor substrate 101 in the conventional charge-coupled device having a two-layer gate electrode structure. First gate electrodes 103 are formed on the gate insulator film 102 at prescribed intervals. Insulator films 104 are formed to cover the front and side surfaces of the first gate electrodes 103. Second gate electrodes 105 are formed on portions of the gate insulator film 102 located between the first gate electrodes 103. Both ends of the second gate electrodes 105 overlap the upper portions of the first gate electrodes 103 through the insulator films 104.

In the conventional charge-coupled device (CCD) having a two-layer gate electrode structure shown in FIG. 11, the interval between the first and second gate electrodes 103 and 105 can be reduced beyond the minimum limit dimension of lithography by forming the insulator films 104 with a thickness smaller than the minimum limit dimension of lithography. Thus, charge transfer efficiency can be improved. Further, the interval between the first and second gate electrodes 103 and 105 can be so reduced beyond the minimum limit dimension of lithography that the areas of the first and second gate electrodes 103 and 105 can be increased. Thus, the area of a region storing electrons is so increased that the quantity of saturation charges is increased and a signal having small noise can consequently be obtained.

In the conventional charge-coupled device (CCD) having a two-layer gate electrode structure shown in FIG. 11, however, the second gate electrodes 105 overlap the upper portions of the first gate electrodes 103 through the insulator films 104 having a small thickness, and hence the parasitic capacitances between the first and second gate electrodes 103 and 105 are inconveniently increased. When the charge-coupled device is driven by applying prescribed voltages to the first and second gate electrodes 103 and 105, therefore, the quantity of charges (current) for obtaining the prescribed voltages is increased due to the large parasitic capacitances. Thus, the quantities of currents flowing through the first and second gate electrodes 103 and 105 having prescribed electrical resistance values are so increased that power consumption is disadvantageously increased.

### SUMMARY OF THE INVENTION

An object of the present invention is to provide a solid state image device capable of improving charge transfer efficiency by reducing the interval between adjacent gate electrodes and reducing power consumption by reducing parasitic capacitances while obtaining a signal having small noise.

Another object of the present invention is to provide a method of fabricating a solid state image device easily allowing fabrication of a solid state image device capable of improving charge transfer efficiency by reducing the interval between adjacent gate electrodes and reducing power consumption by reducing parasitic capacitances while obtaining a signal having small noise.

A solid state image device according to a first aspect of the present invention comprises a gate insulator film formed on a semiconductor substrate, a first gate electrode, formed on the gate insulator film, having a substantially flat upper surface and a second gate electrode formed on the gate insulator film through an insulator film having a thickness smaller than the minimum limit dimension of lithography to be adjacent to the first gate electrode without overlapping the first gate electrode.

In the solid state image device according to the first aspect, having the second gate electrode provided to be adjacent to the first gate electrode through the insulator film having the thickness smaller than the minimum limit dimension of lithography as hereinabove described, the interval between the first and second gate electrodes adjacent to each other can be reduced beyond the minimum limit dimension of lithography, thereby improving charge transfer efficiency. Further, the areas of the gate electrodes can be increased by reducing the interval between the adjacent gate electrodes beyond the minimum limit dimension of lithography, thereby increasing the area of a region storing electrons. Thus, the quantity of saturation charges can be so increased as to obtain a signal having small noise. Further, the parasitic capacitance between the first and second gate electrodes can be inhibited from increase due to the second gate electrode provided to be adjacent to the first gate electrode without overlapping the first gate electrode. When the solid state image device is driven by applying prescribed voltages to the first and second gate electrodes, therefore, the quantity of charges (current) for obtaining the prescribed voltages can be inhibited from increase resulting from a large parasitic capacitance. Consequently, the quantities of currents flowing through the first and second gate electrodes having prescribed electrical resistance values can be so reduced as to reduce power consumption. Thus, charge transfer efficiency can be improved and power consumption can be reduced in the solid state image device according to the first aspect while obtaining a signal having small noise.

In the aforementioned solid state image device according to the first aspect, the insulator film preferably includes a thermal oxide film. According to this structure, the interval between the first and second gate electrodes adjacent to each other can be easily reduced beyond the minimum limit dimension of lithography by reducing the thickness of the thermal oxide film beyond the minimum limit dimension of lithography.

In the aforementioned solid state image device according to the first aspect, the second gate electrode has a substantially flat upper surface. According to this structure, not only the first gate electrode but also the second gate electrode has a flat upper surface, whereby the surface of the solid state image device can be flattened. In this case, the upper surfaces of the first and second gate electrodes are preferably substantially flush with each other. According to this structure, the surface of the solid state image device can be further flattened. In this case, further, the upper surface of the insulator film is preferably substantially flush with the upper surfaces of the first and second gate electrodes. According to this structure, the surface of the solid state image device can be entirely flattened.

In the aforementioned solid state image device according to the first aspect, the gate insulator film preferably includes an insulator film at least partially having an oxidation inhibiting function. According to this structure, the semiconductor substrate can be inhibited from oxidation in thermal oxidation for forming thermal oxide films on the side surfaces of the first gate electrode as compared with a case of providing no insulator film having an oxidation inhibiting function.

In the aforementioned solid state image device according to the first aspect, the gate insulator film may include a first gate insulator film and a second gate insulator film formed on the first gate insulator film. In this case, at least either the first gate insulator film or the second gate insulator film preferably has an oxidation inhibiting function. According to this structure, the gate insulator film having the oxidation inhibiting function can be easily obtained.

A method of fabricating a solid state image device according to a second aspect of the present invention comprises steps of forming a gate insulator film on a semiconductor substrate, forming a plurality of first gate electrodes having substantially flat upper surfaces on the gate insulator film at a prescribed interval, forming insulator films on the side surfaces of the first gate electrodes and forming a second gate electrode adjacent to the first gate electrodes without overlapping the first gate electrodes through the insulator films by depositing a second gate electrode layer to fill up a region located between the first gate electrodes and thereafter removing an excess depositional portion of the second gate electrode layer by polishing.

In the method of fabricating a solid state image device according to the second aspect, as hereinabove described, the insulator films are formed on the side surfaces of the first gate electrodes, the second gate electrode layer is thereafter deposited to fill up the region located between the first gate electrodes and the excess depositional portion of the second gate electrode layer is removed by polishing thereby forming the second gate electrode adjacent to the first gate electrodes through the insulator films so that the interval between the adjacent first and second gate electrodes can be reduced beyond the minimum limit dimension of lithography when the aforementioned insulator films are formed to have a thickness smaller than the minimum limit dimension of lithography, whereby charge transfer efficiency can be improved. Further, the areas of the gate electrodes can be increased by reducing the interval between the adjacent gate electrodes beyond the minimum limit dimension of lithography, whereby the area of a region storing electrons can be increased. Thus, the quantity of saturation charges is so increased that a signal having small noise can be obtained. Further, the second gate electrode is formed to be adjacent to the first gate electrodes without overlapping the first gate electrodes so that the parasitic capacitances between the first and second gate electrodes can be inhibited from increase. When the solid state image device is driven by applying prescribed voltages to the first and second gate electrodes, therefore, the quantity of charges (current) for obtaining the prescribed voltages can be inhibited from increase resulting from large parasitic capacitances. Consequently, the quantities of currents flowing through the first and second gate electrodes having prescribed electrical resistance values can be so reduced as to reduce power consumption. Thus, a solid state image device capable of improving charge transfer efficiency and reducing power consumption while obtaining a signal having small noise can be easily fabricated according to the second aspect.

In the aforementioned method of fabricating a solid state image device according the second aspect, the step of forming the second gate electrode preferably includes a step of depositing the second gate electrode layer having a thickness substantially identical to the thickness of the first gate electrodes to fill up the region located between the first gate electrodes. According to this structure, the second gate electrode having the thickness identical to that of the first gate electrodes can be formed by removing the excess depositional portion of the second gate electrode layer by polishing.

In the aforementioned method of fabricating a solid state image device according to the second aspect, the step of forming the second gate electrode preferably includes a step of forming the second gate electrode having a substantially flat upper surface by removing the excess depositional portion of the second gate electrode layer by polishing. According to this structure, not only the first gate electrodes but also the second gate electrode has a flat upper surface, whereby the surface of the solid state image device can be flattened. In this case, the step of forming the second gate electrode preferably includes a step of forming the second gate electrode having an upper surface substantially flush with the upper surfaces of the first gate electrodes by removing the excess depositional portion of the second gate electrode layer by polishing. According to this structure, the first and second gate electrodes can be flatly formed to be flush with each other, whereby the surface of the solid state image device can be further flattened.

The aforementioned method of fabricating a solid state image device according to the second aspect preferably further comprises a step of forming a polishing stopper film on the first gate electrodes in advance of the step of forming the second gate electrode, and the step of forming the second gate electrode preferably includes a step of forming the second gate electrode adjacent to the first gate electrodes without overlapping the first gate electrodes through the insulator films by polishing the excess depositional portion of the second gate electrode layer through the polishing stopper film serving as a stopper. According to this structure, the second gate electrode adjacent to the first gate electrodes without overlapping the first gate electrodes can be easily formed.

In the aforementioned method of fabricating a solid state image device according to the second aspect, the step of forming the insulator films on the side surfaces of the first gate electrodes preferably includes a step of forming thermal oxide films on the side surfaces of the first gate electrodes by thermally oxidizing the side surfaces of the first gate electrodes. According to this structure, the interval between the adjacent first and second gate electrodes can be easily reduced beyond the minimum limit dimension of lithography by forming the thermal oxide films to have a thickness smaller than the minimum limit dimension of lithography. In this case, the step of forming the thermal oxide films preferably includes a step of forming the thermal oxide films having a thickness smaller than the minimum limit dimension of lithography.

In the method of fabricating a solid state image device including the aforementioned step of forming the thermal oxide films, the step of forming the gate insulator film preferably includes a step of forming the gate insulator film including an insulator film at least partially having an oxidation inhibiting function. According to this structure, the semiconductor substrate can be inhibited from oxidation in thermal oxidation for forming the thermal oxide films on the side surfaces of the first gate electrodes as compared with a case of providing no insulator film having an oxidation inhibiting function.

In the aforementioned method of fabricating a solid state image device according to the second aspect, the step of forming the gate insulator film may include steps of forming a first gate insulator film and forming a second gate insulator film on the first gate insulator film. In this case, at least either the first gate insulator film or the second gate insulator film preferably has an oxidation inhibiting function. According to this structure, the gate insulator film having the oxidation inhibiting function can be easily formed.

The aforementioned method of fabricating a solid state image device according to the second aspect preferably further comprises a step of forming an impurity region in a self-aligned manner on a portion of the semiconductor substrate located under a region formed with the second gate electrode by ion-implanting an impurity into the semiconductor substrate through at least the first gate electrodes serving as masks in advance of the step of forming the second gate electrode. According to this structure, a region formed with the impurity region can be prevented from dispersion dissimilarly to a case of forming the impurity region through a mask of a resist film. Thus, charge transfer efficiency can be prevented from reduction resulting from dispersion of the region formed with the impurity region, whereby a solid state image device having superior charge transfer efficiency can be easily formed.

In the method of fabricating a solid state image device including the aforementioned step of forming the impurity region, the step of forming the impurity region may include a step of ion-implanting the impurity into the semiconductor substrate through the first gate electrodes and the insulator films serving as masks. According to this structure, the impurity region can be formed only under the region formed with the second gate electrode.

In the method of fabricating a solid state image device including the aforementioned step of forming the impurity region, the step of forming the impurity region may include steps of forming a mask layer to partially cover the region formed with the second gate electrode and ion-implanting the impurity into the semiconductor substrate through the first gate electrodes and the mask layers serving as masks. According to this structure, the impurity region can be formed only on a region corresponding to the prescribed second gate electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a charge-coupled device according to an embodiment of the present invention;

FIGS. 2 to 8 are sectional views for illustrating a process of fabricating the charge-coupled device according to the embodiment shown in FIG. 1;

FIG. 9 is a sectional view showing a charge-coupled device according to a first modification of the embodiment of the present invention;

FIG. 10 is a sectional view showing a charge-coupled device according to a second modification of the embodiment of the present invention; and

FIG. 11 is a sectional view showing a conventional charge-coupled device having a two-layer gate electrode structure.

### DESCRIPTION OF THE PREFERRED EMBODIMENTS

An embodiment of the present invention is now described with reference to the drawings.

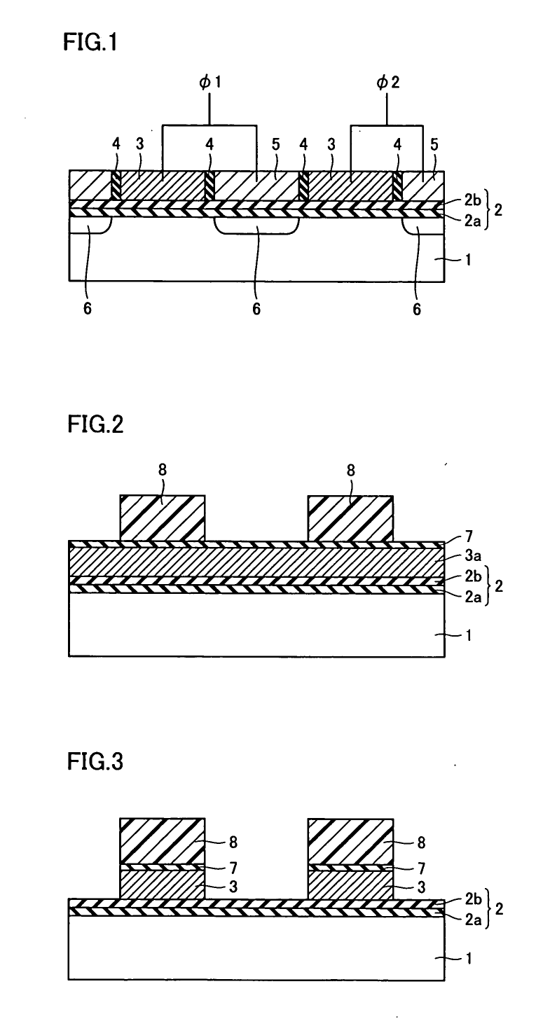

Referring to FIG. 1, the present invention is applied to a two-phase drive charge-coupled device according to this embodiment.

In the charge-coupled device according to this embodiment, a silicon oxide film (SiO₂ film) 2a having a thickness of about 10 nm to about 50 nm is formed on a silicon substrate 1, as shown in FIG. 1. A silicon nitride film (SiN film) 2b having a thickness of about 30 nm to about 100 nm is formed on the silicon oxide film 2a. The silicon oxide film 2a and the silicon nitride film 2b constitute a gate insulator film 2. The silicon substrate 1 is an example of the “semiconductor substrate” in the present invention, and the silicon nitride film 2b is an example of the “insulator film having an oxidation inhibiting function” in the present invention.

According to this embodiment, first gate electrodes 3 and second gate electrodes 4 are formed on the gate insulator film 2 to be adjacent to each other through thermal oxide films 4. The second gate electrodes 5 are provided to be adjacent to the first gate electrodes 3 without overlapping the first gate electrodes 3. The first gate electrodes 3 consist of polysilicon films having a thickness of about 40 nm to about 80 nm, and have substantially flat upper surfaces. The second gate electrodes 5 consist of polysilicon films having a thickness substantially identical to that of the first gate electrodes 3 and have substantially flat upper surfaces. The upper surfaces of the first and second gate electrodes 3 and 5 are substantially flush with each other. The upper surfaces of the thermal oxide films 4 are also flush with those of the first and second gate electrodes 3 and 5. The thermal oxide films 4 are formed by thermally oxidizing the side surfaces of the first gate electrodes 3 consisting of the polysilicon films, and have a thickness (about 20 nm to about 100 nm) smaller than the minimum limit dimension of lithography. The thermal oxide films 4 are examples of the “insulator film(s)” in the present invention.

According to this embodiment, impurity regions 6 are formed on surface portions of the silicon substrate 1 located under the second gate electrodes 5.

An interlayer dielectric film (not shown) of silicon oxide is formed to cover the overall surface, while contact holes (not shown) reaching the first and second gate electrodes 3 and 5 are formed in the interlayer dielectric film. The first and second gate electrodes 3 and 5 are connected with upper wiring layers (not shown) through the contact holes.

In the charge-coupled device (CCD) according to this embodiment, charges are transferred by applying different two-phase voltages φ1 and φ2 to two pairs of the first and second gate electrodes 3 and 5.

According to this embodiment, as hereinabove described, the second gate electrodes 5 are provided to be adjacent to the first gate electrodes 3 through the thermal oxide films 4 having the thickness smaller than the minimum limit dimension of lithography so that the interval between the adjacent first and second gate electrodes 3 and 5 can be reduced beyond the minimum limit dimension of lithography, whereby charge transfer efficiency can be improved. Further, the interval between the adjacent first and second gate electrodes 3 and 5 can be so reduced beyond the minimum limit dimension of lithography that the areas of the first and second gate electrodes 3 and 5 can be increased. Thus, the area of a region storing electrons is so increased that the quantity of saturation charges is increased, whereby a signal having small noise can be obtained as a result.

According to this embodiment, as hereinabove described, the second gate electrodes 5 are provided to be adjacent to the first gate electrodes 3 without overlapping the first gate electrodes 3, whereby the parasitic capacitances between the first and second gate electrodes 3 and 5 can be inhibited from increase. When the charge-coupled device is driven by applying prescribed voltages to the first and second gate electrodes 3 and 5, therefore, the quantity of charges (current) for obtaining the prescribed voltages can be inhibited from increase resulting from large parasitic capacitances. Consequently, the quantities of currents flowing through the first and second gate electrodes 3 and 5 having prescribed electrical resistance values can be so reduced as to reduce power consumption.

According to this embodiment, in addition, the silicon nitride film 2b having an oxidation inhibiting function is so arranged as the upper layer of the gate insulator film 2 that the silicon substrate 1 located under the gate insulator film 2 can be inhibited from oxidation in thermal oxidation for forming the thermal oxide films 4 on the side surfaces of the first gate electrodes 3 in a fabrication step described later.

A process of fabricating the charge-coupled device according to this embodiment is described with reference to FIGS. 1 to 7.

First, the silicon substrate 1 is heat-treated at about 850° C. to about 1050° C., thereby forming the silicon oxide film 2a having the thickness of about 10 nm to about 50 nm on the surface of the silicon substrate 1. Then, the silicon nitride film 2b having the thickness of about 30 nm to about 100 nm is formed by low-pressure chemical vapor deposition (LPCVD) under a temperature condition of about 600° C. to about 800° C. Thus, the gate insulator film 2 consisting of the silicon oxide film 2a and the silicon nitride film 2b is formed.

Thereafter a polysilicon film 3a having a thickness of about 40 nm to about 80 nm is formed by CVD. A silicon nitride film 7 having a thickness of about 5 nm to about 20 nm is formed on the polysilicon film 3a by low-pressure CVD. This silicon nitride film 7 functions as a stopper film in a CMP (chemical mechanical polishing) step described later. The silicon nitride film 7 is an example of the “polishing stopper film” in the present invention. Thereafter resist films 8 are formed on prescribed regions of the silicon nitride film 7.

The resist films 8 are employed as masks for etching the silicon nitride film 7 and the polysilicon film 3a, thereby forming the first gate electrodes 3 consisting of patterned portions of the polysilicon film 3a and silicon nitride films 7 shown in FIG. 3.

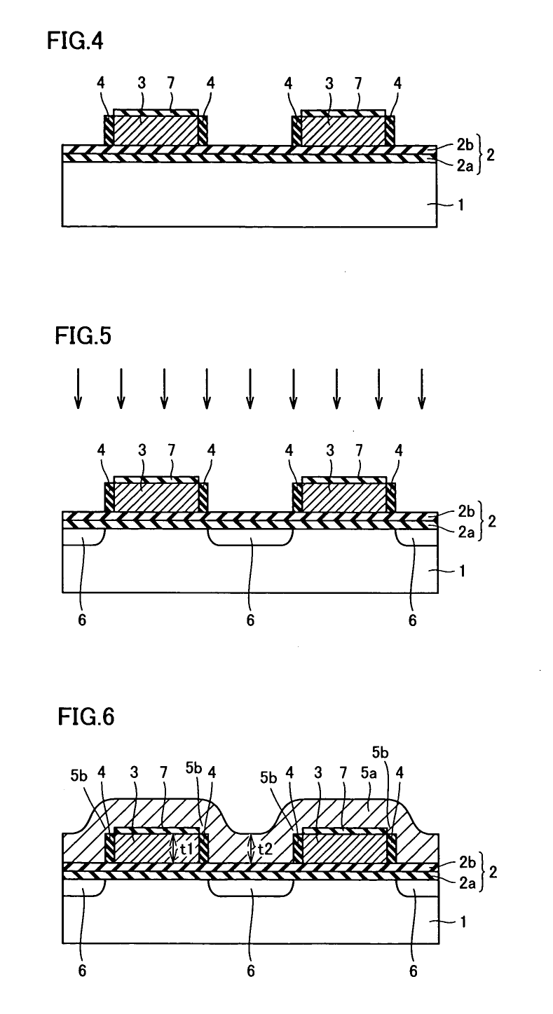

As shown in FIG. 4, thermal oxidation is performed in an O₂ or H₂O atmosphere under a temperature condition of about 750° C. to about 900° C., thereby forming the thermal oxide films 4 on the side surfaces of the first gate electrodes 3. The thermal oxide films 4 are formed with the thickness of about 20 nm to about 100 nm smaller than the minimum limit dimension of lithography. In formation of the thermal oxide films 4, the silicon nitride film 2b constituting the upper layer of the gate insulator film 2 can inhibit the silicon substrate 1 located under the gate insulator film 2 from oxidation.

As shown in FIG. 5, the first gate electrodes 3, the silicon nitride films 7 and the thermal oxide films 4 are employed as masks for ion-implanting an impurity into the surface of the silicon substrate 1, thereby forming the p- or n-type impurity regions 6. The impurity regions 6 are so formed that the potentials of the impurity regions 6 can differ from those of regions, formed with no impurity regions 6, located under the first gate electrodes 3. Thus, regions located under the adjacent first and second gate electrodes 3 and 5 (see FIG. 1) can have potentials different from each other. Consequently, the charge-coupled device can be driven with the two-phase voltages φ1 and φ2. In the aforementioned ion implantation step, boron (B) ions are implanted under conditions of injection energy of about 60 KeV to about 120 KeV and a dose of about 1×10¹¹ cm⁻³ to about 1×10¹² cm⁻³. Thus, the impurity regions 6 having an injection depth of about 130 nm to about 270 nm are formed on the surface of the silicon substrate 1.

Then, a polysilicon film 5a having a thickness of about 40 nm to about 80 nm is formed by CVD, to cover the overall surface. The polysilicon film 5a is an example of the “second gate electrode layer” in the present invention. The polysilicon film 5a is so deposited that the thickness t2 of portions located above the impurity regions 6 is substantially identical to the thickness t1 of the first gate electrodes 3. Excess depositional portions of the polysilicon film 5a are removed by CMP with slurry for the polysilicon film 5a. At this time, the silicon nitride films 7 function as polishing stoppers.

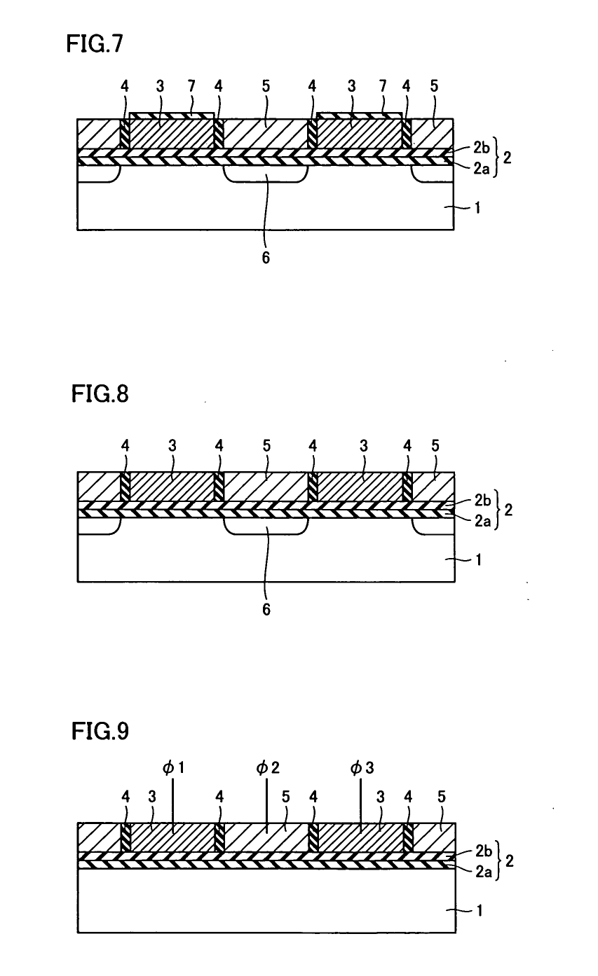

Excess depositional portions 5b of the polysilicon film 5a located in the vicinity of the thermal oxide films 4 are also polished to be flattened due to the action of the slurry for the polysilicon film 5a, whereby the second gate electrodes 5 of polysilicon having the thickness substantially identical to that of the first gate electrodes 3 and flat upper surfaces are finally formed as shown in FIG. 7. The second gate electrodes 5 are formed to be adjacent to the first gate electrodes 3 through the thermal oxide films 4 having the thickness of about 20 nm to about 100 nm smaller than the minimum limit dimension of lithography without overlapping the first gate electrodes 3. Thereafter the silicon nitride films 7 located on the first gate electrodes 3 are removed by wet etching with phosphoric acid, thereby obtaining the shape shown in FIG. 8.

The charge-coupled device according to this embodiment is formed in the aforementioned manner. Thereafter the interlayer dielectric film (not shown) is formed on the overall surface and the contact holes (not shown) reaching the first and second gate electrodes 3 and 5 are thereafter formed in the interlayer dielectric film. The first and second gate electrodes 3 and 5 are electrically connected with the upper wiring layers (not shown) through the contact holes.

In the fabrication process according to this embodiment, as hereinabove described, the thermal oxide films 4 having the thickness smaller than the minimum limit dimension of lithography are formed on the side surfaces of the first gate electrodes 3, the polysilicon film 5a is thereafter deposited to fill up the regions located between the first gate electrodes 3 and the excess depositional potions of the polysilicon film 5a are removed by CMP, whereby the second gate electrodes 5 adjacent to the first gate electrodes 3 can be easily formed without overlapping the first gate electrodes 3. Thus, the parasitic capacitances between the first and second gate electrodes 3 and 5 can be inhibited from increase. When the charge-coupled device is driven by applying prescribed voltages to the first and second gate electrodes 3 and 5, therefore, the quantity of charges (current) for obtaining the prescribed voltages can be inhibited from increase resulting from large parasitic capacitances. Consequently, the quantities of currents flowing through the first and second gate electrodes 3 and 5 having prescribed electrical resistance values can be so reduced as to reduce power consumption. In addition, the interval between the adjacent first and second gate electrodes 3 and 5 can be reduced beyond the minimum limit dimension of lithography, whereby a charge-coupled device improved in transfer efficiency and capable of obtaining a signal having small noise can be easily formed.

Thus, according to the fabrication process of this embodiment, a charge-coupled device capable of improving charge transfer efficiency and reducing power consumption while obtaining a signal having small noise can be easily fabricated.

In the fabrication process according to this embodiment, as hereinabove described, the first gate electrodes 3, the silicon nitride films 7 and the thermal oxide films 4 are employed as masks for ion-implanting the impurity, whereby the impurity regions 6 can be formed on the surface portions of the silicon substrate 1 located under the regions formed with the second gate electrodes 5 in a self-aligned manner. Thus, the regions formed with the impurity regions 6 can be prevented from dispersion dissimilarly to a case of forming the impurity regions 6 through masks of resist films. Consequently, the charge transfer efficiency can be prevented from reduction resulting from dispersion of the regions formed with the impurity regions 6, whereby a charge-coupled device having superior charge transfer efficiency can be easily formed.

Although the present invention has been described and illustrated in detail, it is clearly understood that the same is by way of illustration and example only and is not to be taken by way of limitation, the spirit and scope of the present invention being limited only by the terms of the appended claims.

For example, while the above embodiment has been described with reference to the two-phase drive charge-coupled device, the present invention is not restricted to this but is also applicable to a three- or four-phase drive charge-coupled device. For example, different three-phase voltages φ1, φ2 and φ3 may be applied to a first gate electrode 3, a second gate electrode 5 adjacent to the right side of this first gate electrode 3 and another first gate electrode 3 adjacent to the right side of this second gate electrode 5 respectively as in a first modification of the embodiment shown in FIG. 9. In the case of the three- or four-phase drive, no impurity region 6 (see FIG. 1) is formed under the second gate electrode 5, dissimilarly to the aforementioned embodiment.

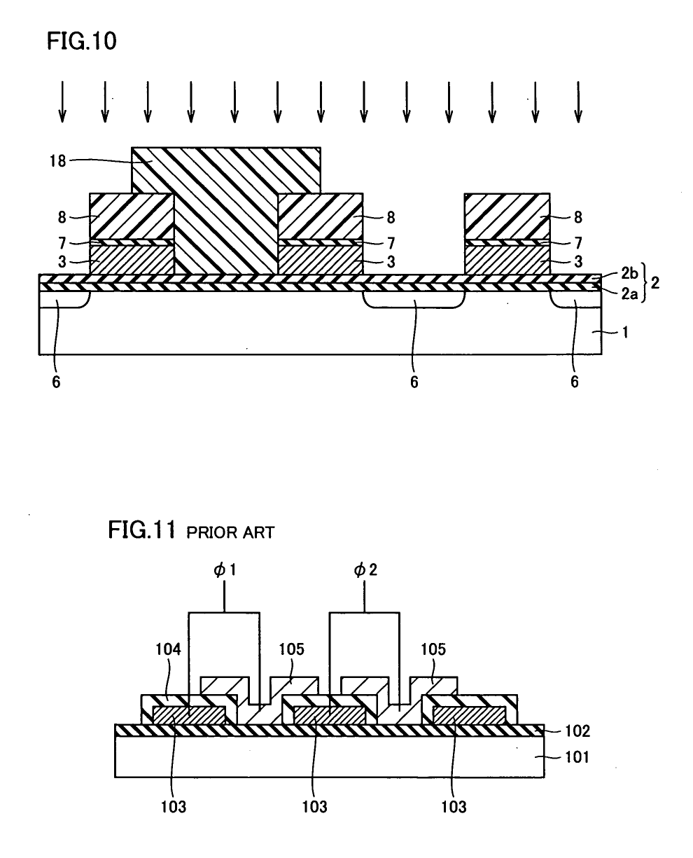

While the thermal oxide films 4 are formed on the side surfaces of the first gate electrodes 3 and the first gate electrodes 3, the silicon nitride films 7 and the thermal oxide films 4 are thereafter employed as masks for forming the impurity regions 6 by ion implantation in the aforementioned embodiment, the present invention is not restricted to this but the first gate electrodes 3 and the resist films 8 may alternatively be employed as masks for forming the impurity regions 6 by ion implantation in the step shown in FIG. 3 before forming the thermal oxide films 4. In order to form an impurity region 6 every fourth, a resist film 18 is formed to cover a region formed with no impurity region 6 as in a second modification of the embodiment shown in FIG. 10. This resist film 18 is an example of the “mask layer” in the present invention. The resist film 18 and other resist films 8 may be employed as masks for ion-implanting an impurity, thereby forming each impurity region 6 every fourth.

What is claimed is:

1. A solid state image device comprising:
a gate insulator film formed on a semiconductor substrate;
a first gate electrode, formed on said gate insulator film, having a substantially flat upper surface; and
a second gate electrode formed on said gate insulator film through an insulator film having a thickness smaller than the minimum limit dimension of lithography to be adjacent to said first gate electrode without overlapping said first gate electrode.

2. The solid state image device according to claim 1, wherein
said insulator film includes a thermal oxide film.

3. The solid state image device according to claim 1, wherein
said second gate electrode has a substantially flat upper surface.

4. The solid state image device according to claim 3, wherein
the upper surfaces of said first gate electrode and said second gate electrode are substantially flush with each other.

5. The solid state image device according to claim 4, wherein
the upper surface of said insulator film is substantially flush with the upper surfaces of said first gate electrode and said second gate electrode.

6. The solid state image device according to claim 1, wherein
said gate insulator film includes an insulator film at least partially having an oxidation inhibiting function.

7. The solid state image device according to claim 1, wherein
said gate insulator film includes a first gate insulator film and a second gate insulator film formed on said first gate insulator film.

8. The solid state image device according to claim 7, wherein
at least either said first gate insulator film or said second gate insulator film has an oxidation inhibiting function.

9. A method of fabricating a solid state image device, comprising steps of:
forming a gate insulator film on a semiconductor substrate;
forming a plurality of first gate electrodes having substantially flat upper surfaces on said gate insulator film at a prescribed interval;
forming insulator films on the side surfaces of said first gate electrodes; and
forming a second gate electrode adjacent to said first gate electrodes without overlapping said first gate electrodes through said insulator films by depositing a second gate electrode layer to fill up a region located between said first gate electrodes and thereafter removing an excess depositional portion of said second gate electrode layer by polishing.

10. The method of fabricating a solid state image device according to claim 9, wherein
said step of forming said second gate electrode includes a step of depositing said second gate electrode layer having a thickness substantially identical to the thickness of said first gate electrodes to fill up said region located between said first gate electrodes.

11. The method of fabricating a solid state image device according to claim 9, wherein
said step of forming said second gate electrode includes a step of forming said second gate electrode having a substantially flat upper surface by removing said excess depositional portion of said second gate electrode layer by polishing.

12. The method of fabricating a solid state image device according to claim 11, wherein
said step of forming said second gate electrode includes a step of forming said second gate electrode having an upper surface substantially flush with the upper surfaces of said first gate electrodes by removing said excess depositional portion of said second gate electrode layer by polishing.

13. The method of fabricating a solid state image device according to claim 9, further comprising a step of forming a polishing stopper film on said first gate electrodes in advance of said step of forming said second gate electrode, wherein
said step of forming said second gate electrode includes a step of forming said second gate electrode adjacent to said first gate electrodes without overlapping said first gate electrodes through said insulator films by polishing said excess depositional portion of said second gate electrode layer through said polishing stopper film serving as a stopper.

14. The method of fabricating a solid state image device according to claim 9, wherein
said step of forming said insulator films on the side surfaces of said first gate electrodes includes a step of forming thermal oxide films on the side surfaces of said first gate electrodes by thermally oxidizing the side surfaces of said first gate electrodes.

15. The method of fabricating a solid state image device according to claim 14, wherein
said step of forming said thermal oxide films includes a step of forming said thermal oxide films having a thickness smaller than the minimum limit dimension of lithography.

16. The method of fabricating a solid state image device according to claim 14, wherein
said step of forming said gate insulator film includes a step of forming said gate insulator film including an insulator film at least partially having an oxidation inhibiting function.

17. The method of fabricating a solid state image device according to claim 9, wherein
said step of forming said gate insulator film includes steps of:
forming a first gate insulator film, and
forming a second gate insulator film on said first gate insulator film.

18. The method of fabricating a solid state image device according to claim 17, wherein
at least either said first gate insulator film or said second gate insulator film has an oxidation inhibiting function.

19. The method of fabricating a solid state image device according to claim 9, further comprising a step of forming an impurity region in a self-aligned manner on a portion of said semiconductor substrate located under a region formed with said second gate electrode by ion-implanting an impurity into said semiconductor substrate through at least said first gate electrodes serving as masks in advance of said step of forming said second gate electrode.

20. The method of fabricating a solid state image device according to claim 19, wherein
said step of forming said impurity region includes a step of ion-implanting said impurity into said semiconductor substrate through said first gate electrodes and said insulator films serving as masks.

21. The method of fabricating a solid state image device according to claim 19, wherein
said step of forming said impurity region includes steps of:
forming a mask layer to partially cover said region formed with said second gate electrode, and
ion-implanting said impurity into said semiconductor substrate through said first gate electrodes and said masks layer serving as masks.
